(19) United States
(12) Patent Application Publication
(10) Pub. No.: US 2006/0273712 A1
(43) Pub. Date: Dec. 7, 2006

(54) Organic electroluminescence display apparatus

(75) Inventor: Hiroyuki Yaegashi, Kanagawa (JP)

Correspondence Address: BIRCH STEWART KOLASCH & BIRCH, PO BOX 747, FALLS CHURCH, VA, 22040-0747, US

(73) Assignee: FUJI PHOTO FILM CO., LTD., Minami-Ashigara-shi (JP)

(21) Appl. No.: 11/432,562

(22) Filed: May 12, 2006

(30) Foreign Application Priority Data
May 13, 2005 (JP) 2005-140624

(51) Int. Cl. H05B 33/12; H01L 51/50

(52) U.S. Cl. 313/503; 313/504; 313/500

(57) ABSTRACT

An organic electroluminescence display apparatus comprising a first substrate 101 and a second substrate 102 adhered to the first substrate, wherein the first substrate 101 comprises a first base substrate 1 having an organic electroluminescence device 2, the organic electroluminescence device 2 comprises a first electrode 3, an organic electroluminescence layer 4, and a second electrode 5 provided in this order from the first base substrate side, the second substrate 102 comprises a second base substrate 6 and a patterned conductive film 7 provided on the second base substrate 6 such that the patterned conductive film 7 faces the first substrate 101, the patterned conductive film 7 has a lower specific resistance than the second electrode 5, and the conductive film 7 is electrically connected to the second electrode 5.

### CROSS-REFERENCE TO RELATED APPLICATION

This application claims priority under 35 USC 119 from Japanese patent Application Nos. 2005-140624, the disclosure of which is incorporated by reference herein.

### BACKGROUND OF THE INVENTION

1. Field of the Invention

The present invention relates to an organic electroluminescence display apparatus, and particularly relates to an organic electroluminescence display apparatus in which the display surface is provided on the side opposite to the substrate, and which at least features a configuration to enhance the aperture ratio for the organic electroluminescence display apparatus.

2. Description of the Related Art

As a display apparatus which can be rendered thin-sized and lightweight, compared to the conventional CRT (cathode ray tube) and LCD (liquid crystal display), the display apparatus which uses an organic electroluminescence (EL) device has attracted a lot of attention in recent years.

Because the organic electroluminescence device is of self-light emission type, it has various features, such as high visibility; independency from view angle, compatibility with a film substrate having a flexibility, thinness and lightness as compared to liquid crystal display apparatuses, and the like.

In the case of conventional organic electroluminescence display apparatuses, an organic electroluminescence device consisting of an anode, an organic electroluminescence layer, and a cathode provided on an insulating substrate is formed, for example by the following manner: an anode made of a transparent conductive film (such as ITO or the like) is formed on an insulating substrate made of a glass substrate; an organic electroluminescence layer including a luminescent layer where electrons and holes are recombined to generate light is formed on this anode; and a cathode made of Al or Mg—Ag alloy or the like is formed on the organic electroluminescence layer.

Further, in order to realize a display having a high definition, development of a display apparatus of active matrix type that has a switching element, such as a thin film transistor (TFT), or the like, together with an organic electroluminescence device is being progressed.

In this active matrix type display apparatus, the switching element, such as a thin film transistor or the like, is formed between the insulating substrate and the organic electroluminescence device, and controls the drive voltage to be applied to the organic electroluminescence device.

The display apparatus having such a structure is of a so-called bottom emission type, in which the light generated in the luminescent layer in the organic electroluminescence layer is taken from the insulating substrate.

In order to realize full colorization in such an organic electroluminescence display apparatus, the luminescent layers differing in emission wavelength are separately produced in the pixel region; for example, the substrate is brought into close contact with a vapor deposition mask having openings at regions corresponding to desired pixels, and the luminescent layers forming the respective RGB colors are formed by moving the vapor deposition mask in the order of RGB, for example.

As described above, in the case of a bottom emission type display apparatus, the light generated in the organic electroluminescence device is taken out from the insulating substrate side; thus if a switching element is formed between the insulating substrate and the organic electroluminescence device, the switching element becomes a light shielding element, which results in substantial reduction in the light emission area per 1 pixel due to the presence of the switching element, thus presenting a problem in that a high light emission efficiency cannot be obtained.

Toward such a problem of light emission efficiency, a so-called top emission type structure has been proposed as a solution, in which the light generated in the luminescent layer is taken out from the side opposite to the insulating substrate side having the switching element formed thereon, i.e., from the cathode side.

In this case, in order to provide the cathode with an optical transparency, a transparent conductive film, such as an ITO film, is used; however, the ITO film presents a problem of high specific resistance.

In addition, optical transparency can be obtained by reducing the thickness of the Ag film, preferably to a thickness of 20 nm or less; however, such a reduction in thickness presents a problem in that a low resistance film cannot be obtained.

Such an increase in resistance of the cathode accompanying increased optical transparency results in an increased voltage drop across the cathode, which causes a problem that, with the size of the organic electroluminescence display apparatus being increased, the non-uniformity in brightness gets worse.

As a solution to such a problem about the brightness non-uniformity, it has been proposed to provide an auxiliary low resistance wiring for the cathode outside the pixel aperture part (as disclosed in Japanese Patent Laid-Open Nos. 2004-207217 and 11-008073, for example). In the following, a conventional top emission type display apparatus will be described with reference to FIGS. 9A and 9B.

FIGS. 9A and 9B are explanatory drawings illustrating a top emission type display apparatus of active matrix type using a conventional organic EL device. FIG. 9A is a plane view showing substantial parts, and FIG. 9B is a schematic cross-sectional view taken along the dot-dash line A-A′ in FIG. 9A. Polycrystal silicon island-like regions 64 are formed on a glass substrate 61 with an SiN film 62 and an SiO₂ film 63 therebetween, and a gate electrode 66 made of Al is provided on the polycrystal silicon island-like regions 64 with a gate insulating film 65 made of an SiO₂ film therebetween; next, an SiO₂ film 67 is provided to cover the entire surface; and then apertures for source/drain regions are formed, and source electrodes 68 and drain electrodes 69 are formed, whereby a TFT as an active element is formed.

Next, after applying positive-type photosensitive polyimide by the spin coating method, only the regions corresponding to the source electrodes 68 are exposed and developed, followed by baking to form a flattened insulating film 70 having contact holes 71 for the source electrodes 68.

Next, an Al film is deposited over the entire surface, then an anode 72 and an auxiliary electrode 73 are formed by patterning the Al film to a prescribed geometry; thereafter, an SiO₂ film 74 is deposited over the entire surface, and then aperture parts to expose the anode 72 and the auxiliary electrode 73 are formed.

Next, using a vapor deposition mask which is positioned such that the non-aperture part corresponds to the auxiliary electrode 73, a hole injection layer, a hole transport layer, and a luminescent layer are sequentially vapor deposited under heat to form an organic EL layer 75, followed by removing the vapor deposition mask, depositing a cathode 76 made of ITO over the entire surface, and electrically connecting the cathode 76 to the auxiliary electrode 73.

Finally, in the same manner as ordinary organic EL devices, a UV adhesive is used for sealing with a sealing plate 77 made of glass in a dried nitrogen atmosphere, whereby a top emission type display apparatus using an organic EL device is completed.

Thus, by connecting the cathode 76 made of ITO, which has a high specific resistance, to the auxiliary electrode 73 made of Al, which has a low specific resistance, the voltage drop due to the cathode 76 is reduced, thereby significantly improving the display characteristics.

On the other hand, in the above-mentioned display apparatus disclosed in Japanese Patent Laid-Open No. 11-008073, an auxiliary wiring is formed on the surfaces of the opposing electrode stripes which are formed so as to intersect with the lower electrode stripes, such that the auxiliary wiring intersects with the lower electrode stripes.

### SUMMARY OF THE INVENTION

However, with the structure of the auxiliary wiring as shown in FIGS. 9A and 9B, since the first electrode and the auxiliary wiring are provided as the same layer, space must be given between the first electrode and the auxiliary wiring; therefore, the light emission area for the organic electroluminescence device is restricted by the width of the auxiliary wiring and the width of the clearance between the first electrode and the auxiliary wiring, presenting a problem in that a high aperture ratio is difficult to achieve.

In addition, with the above-mentioned display apparatus disclosed in Japanese Patent Laid-Open Publication No. 11-008073, the auxiliary wiring is formed in the shape of stripes on the opposing electrode stripes using a mask provided with openings in a prescribed shape. However, the mask is required to be tightly contacted with the opposing electrode formed on the substrate, which causes problems in that the mask flaw can lower the yield, and in that it is difficult to reduce the width of the auxiliary wiring.

The present invention has been made in view of the above situation, and provides an organic electroluminescence display apparatus.

A first aspect of the present invention provides an organic electroluminescence display apparatus. The organic electroluminescence display apparatus comprises a first substrate and a second substrate adhered to the first substrate. The first substrate comprises a first base substrate having an organic electroluminescence device that comprises a first electrode, an organic electroluminescence layer, and a second electrode provided in this order from the first base substrate. The second substrate comprises a second base substrate and a patterned conductive film with a lower specific resistance than the second electrode. The patterned conductive film is provided on the side of the second base substrate which side is near to the first substrate. The conductive film is electrically connected to the second electrode.

### BRIEF DESCRIPTION OF THE DRAWINGS

FIG. 1 is a configuration drawing illustrating the principle of embodiments of the present invention.

FIG. 2 is an explanatory drawing illustrating the manufacturing process for a top emission type display apparatus using an organic EL device described in EXAMPLE 1 according to the present invention.

FIG. 3 is a schematic cross-sectional view of substantial parts of a top emission type display apparatus using an organic EL device described in EXAMPLE 2 according to the present invention.

FIG. 4 is a schematic cross-sectional view of substantial parts of a top emission type display apparatus using an organic EL device described in EXAMPLE 3 according to the present invention.

FIG. 5 is a schematic cross-sectional view of substantial parts of a top emission type display apparatus using an organic EL device described in EXAMPLE 4 according to the present invention.

FIG. 6 is a schematic cross-sectional view of substantial parts of a top emission type display apparatus using an organic EL device described in EXAMPLE 5 according to the present invention.

FIG. 7 is an explanatory drawing illustrating a manufacturing process up to halfway thereof for a top emission type display apparatus of active matrix type using an organic EL device described in EXAMPLE 6 according to the present invention.

FIG. 8 is an explanatory drawing illustrating a manufacturing process subsequent to that shown in FIG. 7 for a top emission type display apparatus of active matrix type using an organic EL device described in EXAMPLE 6 according to the present invention.

FIGS. 9A and 9B are explanatory drawings illustrating a top emission type display apparatus of active matrix type using a conventional organic EL device.

### DESCRIPTION OF THE PRESENT INVENTION

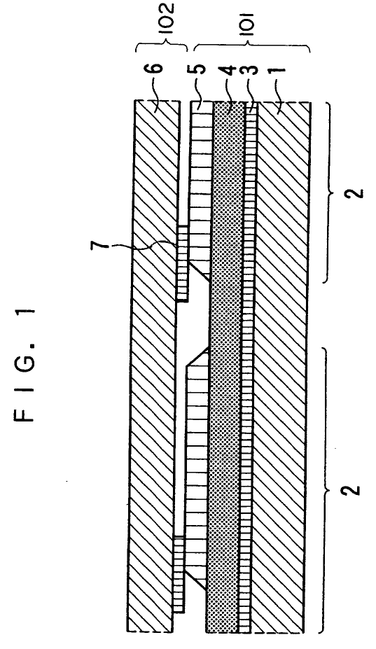

FIG. 1 is a configuration drawing illustrating the principle of embodiments of the present invention. In the following, embodiments of the invention are described with reference to FIG. 1.

In the embodiments, an organic electroluminescence display apparatuses are provided in which a first substrate 101 is adhered to a second substrate 102. The first substrate 101 comprises a first base substrate 1 having an organic electroluminescence device 2. The organic electroluminescence device 2 comprises a first electrode 3, an organic electroluminescence layer 4, and a second electrode 5 provided in this order from the first base substrate side. The second substrate 102 comprises a second base substrate 6 having thereon a patterned conductive film 7 with a lower specific resistance than the second electrode 5, such that the patterned conductive film 7 faces the first substrate 101 and such that the conductive film 7 is electrically connected to the second electrode 5.

Since the patterned conductive film 7 with a low specific resistance is provided as the auxiliary electrode on the second base substrate 6, it is not necessary to secure clearance between the organic electroluminescence layer 4 and the auxiliary wiring connection hole, whereby the aperture ratio can be increased, and the manufacturing yield can be improved.

Such a configuration is important for a display apparatus of so-called top emission type or the like in which the second electrode 5 is made of a material having such an optical transparency as to give a transmittance for the emitted light of 50% or higher (preferably, 80% or higher).

In this case, the transparency of the second electrode 5 can be achieved by the use of at least one of a translucent metallic thin film or an oxide transparent conductive film.

In addition, the surface of the conductive film 7 that contacts with the second base substrate 6 preferably has such a structure as to prevent reflection of outside light, so as to improve the display characteristics.

The structure that prevents reflection of outside light is typically either a concavo-convex structure or a black matrix.

In addition, the second base substrate 6 may be flexible. When the second base substrate 6 is flexible, the organic electroluminescence display apparatus can be made thinner and its weight can be reduced.

In addition, the above-described configuration can be applied not only to a display apparatus of passive matrix type that has a simple matrix structure, but also to a display apparatus of active matrix type that is provided with a switching element, whereby display with a higher definition can be obtained.

In an embodiment, the conductive film 7 in a display apparatus of active matrix type can be either in the shape of stripes or in the shape of a matrix, and is connected to the second base substrate 6 in regions outside the pixel regions, so that the presence of the conductive film 7 has no effect on the aperture ratio.

In addition, when the display surface is provided on the second base substrate 6 side, the first electrode 3 may be opaque; in such a case, the first electrode 3 is preferably a metallic film with a lower specific resistance.

When a double-face display apparatus is desired, the first electrode 3 has to be made of a material having optical transparency.

In an embodiment of the present invention, a top emission type display apparatus comprises a first substrate and a second substrate adhered to the first substrate. The first substrate comprises a first base substrate (such as glass) and an organic electroluminescence device provided on the first base substrate. The organic electroluminescence device comprises at least a first electrode, an organic electroluminescence layer, and a second electrode provided in this order on the first base substrate. The second substrate comprises a second base substrate and a patterned auxiliary electrode having a specific resistance lower than that of the second electrode such that the auxiliary electrode is electrically connected to the second electrode.

### EXAMPLE 1

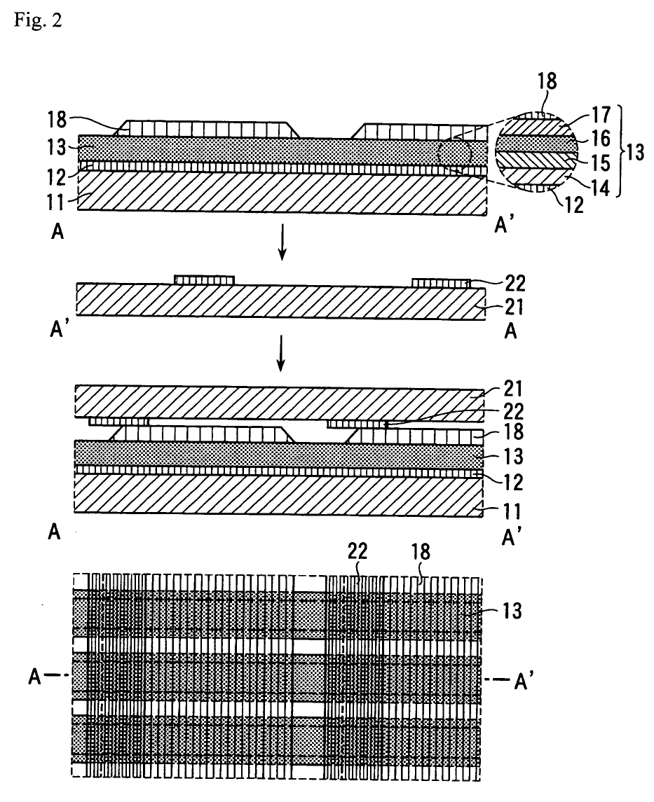

Herein, with reference to FIG. 2, a top emission type display apparatus using an organic EL device of EXAMPLE 1 according to the present invention will be described.

First, an anode 12 made of Al is provided in the shape of stripes on a first glass base substrate 11, and then an organic EL layer 13 is deposited thereon using a vapor deposition mask having openings in predetermined regions.

The organic EL layer 13 in this case may be formed by sequentially vapor-depositing a hole injection layer 14 made of MTDATA [4,4′,4″-tris(3-methylphenylphenylamino)triphenylamine] with a thickness of, for example, 30 nm; a hole transport layer 15 made of α-NPD (N,N′-dinaphthyl-N,N′-diphenyl-[1,1′-biphenyl]-4,4′-diamine) with a thickness of, for example, 20 nm; a luminescent layer 16 made of host Alq₃ (tris(8-hydroxyquinolinate)aluminum) doped with a luminescent material, t(npa)py (1,3,6,8-tetra[N-(naphthyl)-N-phenylamino]pyrene with a thickness of, for example, 30 nm; and an electron transport layer 17 made of Alq₃ with a thickness of, for example, 20 nm.

Next, using a vapor deposition mask for electrode, a cathode 18 made of a conductive material with an optical transparency giving a transmittance of 50% or higher for light (e.g., ITO) is formed in the shape of stripes such that the cathode stripes cross the anode 12.

On the other hand, on the second glass base substrate 21, an auxiliary electrode 22 made of a material (e.g., Al) with a specific resistance lower than that of ITO constituting the cathode 18 is formed in the shape of stripes with the same pitch as that of the stripes of the cathode 18. The width of the stripes of the auxiliary electrode 22 is narrower than that of the stripes of the cathode 18.

Next, the auxiliary electrode 22 is positioned relative to the cathode 18 such that the auxiliary electrode 22 contacts with one end of the cathode 18, and then UV adhesive is used to perform sealing in a dried nitrogen atmosphere, whereby a top emission type display apparatus using an organic EL device according to EXAMPLE 1 of the present invention is completed.

The first three parts in FIG. 2 are schematic cross-sections taken along the dot-dash line A-A′ in the fourth parts (plane view) in the same figure.

With the top emission type display apparatus using the organic EL device according to EXAMPLE 1 of the present invention, a voltage is applied between the anode 12 and the cathode 18 via the auxiliary electrode 22, whereby holes are injected from the anode 12 into the organic EL layer 13 while electrons are injected from the cathode 18 into the organic EL layer 13. The injected holes are transported to the luminescent layer 16 via the hole transport layer 15 while the injected electrons are transported to the luminescent layer 16 via the electron transport layer 17.

The holes and electrons thus transported to the luminescent layer 16 recombine in the luminescent layer 16 to generate light, and the light generated is taken out from the cathode 18 side having optical transparency.

Thus, in EXAMPLE 1 of the present invention, ITO, which has a high specific resistance, is used as the cathode material in order to render optical transparency to the cathode 18; however, since the auxiliary electrode 22 made of Al, which has lower specific resistance, is provided on the second glass base substrate 21 side and is electrically connected to the cathode 18, the aperture accuracy of the mask need not be considered, and the number of times the vapor deposition mask is brought into contact with the first glass base substrate 11 having thereon the organic EL layer 13 can be decreased, so that the reduction in yield due to flaws caused by the mask can be prevented, as compared to the case where an auxiliary wiring 22 is formed on the cathode 18 by mask vapor deposition after the formation of the cathode 18.

In addition, there is no need for providing the auxiliary electrode 22 on the first glass base substrate 11 side, thus the dedicated area for the organic EL layer 13 is not restricted, whereby the aperture ratio can be increased.

### EXAMPLE 2

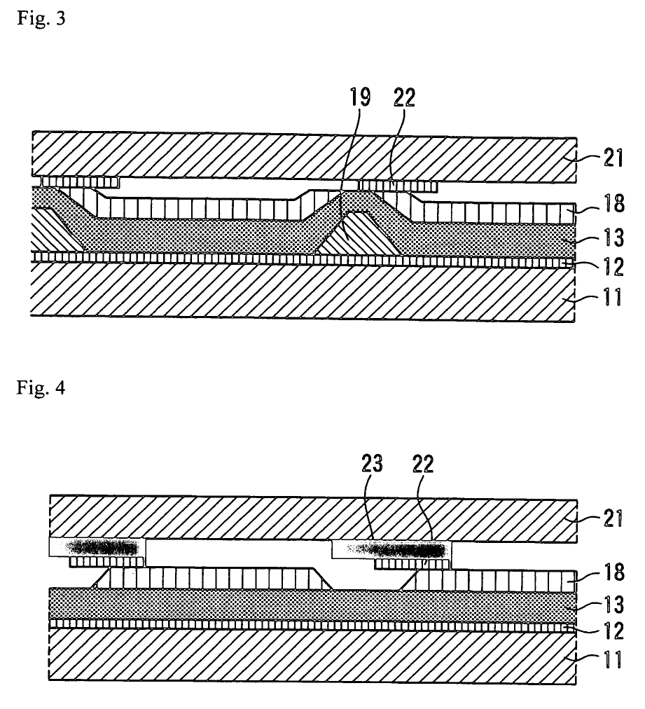

Next, with reference to FIG. 3, a top emission type display apparatus using an organic EL device according to EXAMPLE 2 of the present invention will be described.

FIG. 3 is a schematic cross-sectional view of substantial portions of a top emission type display apparatus using an organic EL device according to EXAMPLE 2 of the present invention, in which a convex insulating film 19 made of a photosensitive polyimide is formed, resulting in a sectional geometry which is different from that in EXAMPLE 1. However, the manufacturing processes other than the formation of the insulating film 19 is the same as those in EXAMPLE 1. In addition, the other signs indicate the same members as those in FIG. 2.

Also in EXAMPLE 2, the aperture ratio can be increased as in EXAMPLE 1, and the reduction in manufacturing yield can be suppressed.

### EXAMPLE 3

Next, with reference to FIG. 4, a top emission type display apparatus using an organic EL device according to EXAMPLE 3 of the present invention will be described. FIG. 4 is a schematic cross-sectional view of substantial portions of a top emission type display apparatus using an organic EL device according to EXAMPLE 3 of the present invention, in which a black matrix 23 made of a black resin is provided between the second glass base substrate 21 and the auxiliary electrode 22. The manufacturing processes other than the formation of the black matrix 23 are the same as that in EXAMPLE 1. In addition, the other signs indicate the same members as those in FIG. 2.

In this case, in order to avoid electrical connection between adjacent stripes of the cathode 18 in adhering the first glass base substrate 11 to the second glass base substrate 21, the auxiliary electrode 22 on the black matrix 23 has a width narrower than that of the black matrix 23, and is formed at a position shifted toward one end of the black matrix 23.

In this EXAMPLE 3, since the black matrix 23 is provided, reflection of outside light can be prevented by the black matrix 23, whereby a higher contrast can be obtained.

### EXAMPLE 4

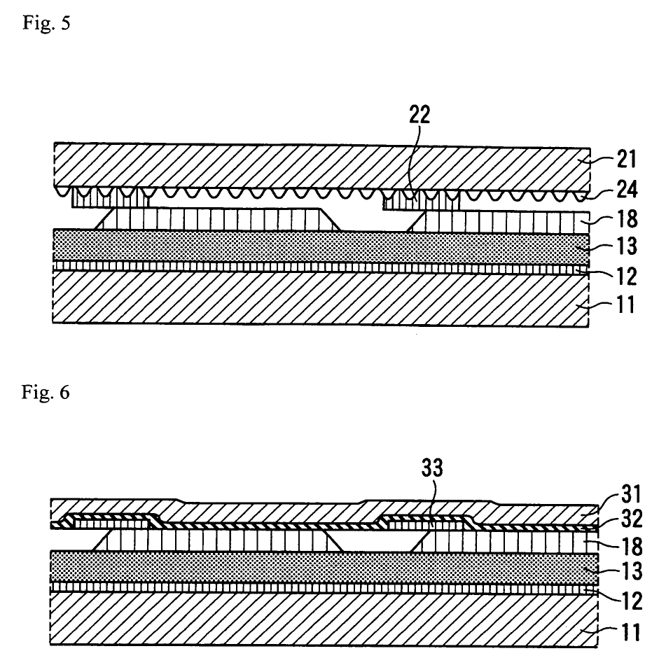

Next, with reference to FIG. 5, a top emission type display apparatus using an organic EL device according to EXAMPLE 4 of the present invention will be described. FIG. 5 is a schematic cross-sectional view of substantial portions of a top emission type display apparatus using an organic EL device according to EXAMPLE 4 of the present invention, in which a concavo-convex structure 24 is formed on the surface of the second glass base substrate 21 that is nearer to the first glass base substrate 11. The surface of the auxiliary electrode 22 that is on the display surface side is provided with a concavo-convex structure owing to the concavo-convex structure 24. The manufacturing processes other than the formation of the concavo-convex structure 24 are the same as that in EXAMPLE 1. In addition, the other signs indicate the same members as those in FIG. 2.

The concavo-convex structure 24 in this case is formed by coating the second glass base substrate 21 with a photosensitive acrylic resin, and then patterning the coated surface into a predetermined concavo-convex shape through a photolithographic process.

In EXAMPLE 4, since the concavo-convex structure 24 is provided, the concavo-convex structure 24 diffuses outside light at regions where the auxiliary electrode 22 is provided, , resulting in reduction in reflection of outside light; therefore, a higher contrast can be obtained.

### EXAMPLE 5

Next, with reference to FIG. 6, a top emission type display apparatus using an organic EL device according to EXAMPLE 5 of the present invention will be described. FIG. 6 is a schematic cross-sectional view of substantial portions of a top emission type display apparatus using an organic EL device according to EXAMPLE 5 of the present invention, in which a transparent film base substrate 31 made of flexible PET (polyethyleneterephthalate) having a hot melt adhesive 32 coated on its surface is provided in place of the second glass base substrate 21. The manufacturing processes other than providing the transparent film base substrate 31 are the same as that in EXAMPLE 1. In addition, the other signs indicate the same members as those in FIG. 2.

In this case, after an auxiliary electrode 33 made of Al is provided on a transparent film base substrate 31 via a hot melt adhesive 32 and the auxiliary electrode 33 is brought into contact with one end of the cathode 18 by adjusting the relative positions, sealing is performed under pressure and heat in a dried nitrogen atmosphere by bringing the first substrate comprising the first glass base substrate 11 and the organic electroluminescent device provided thereon into close contact with the second substrate comprising the transparent film base substrate 31 and the auxiliary electrode 33 provided thereon via the adhesive 32. A top emission type display apparatus using an organic EL device according to EXAMPLE 5 of the present invention is completed in this way.

In this EXAMPLE 5, since the transparent film base substrate 31 is used as the second base substrate, the display apparatus can be made more lightweight and thinner, thus being suitable for use as a display panel for portable equipments.

### EXAMPLE 6

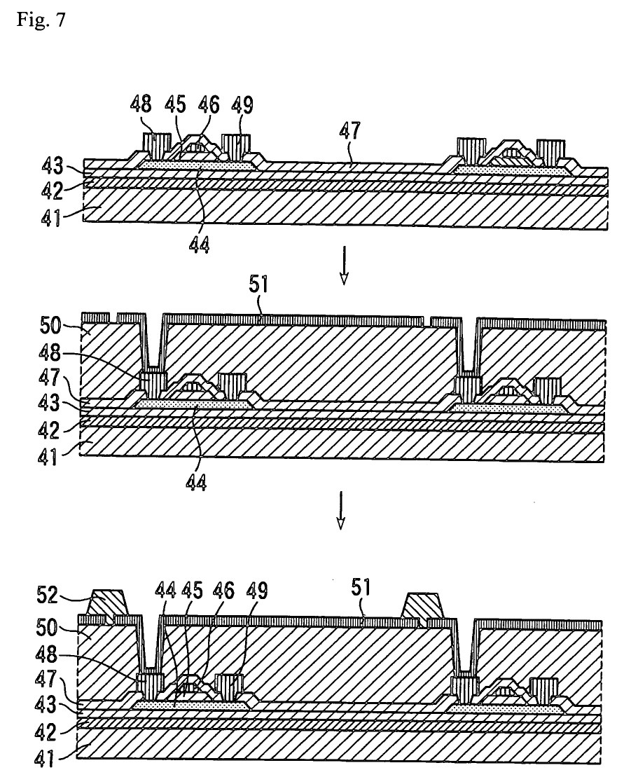

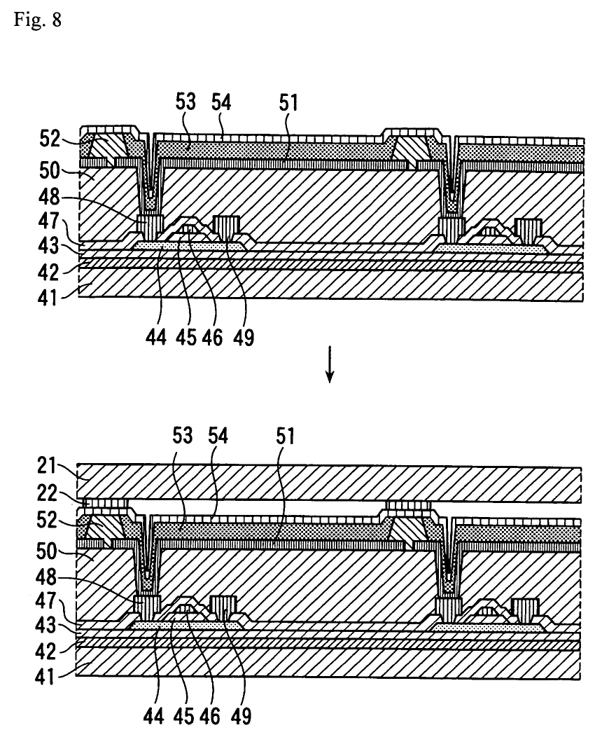

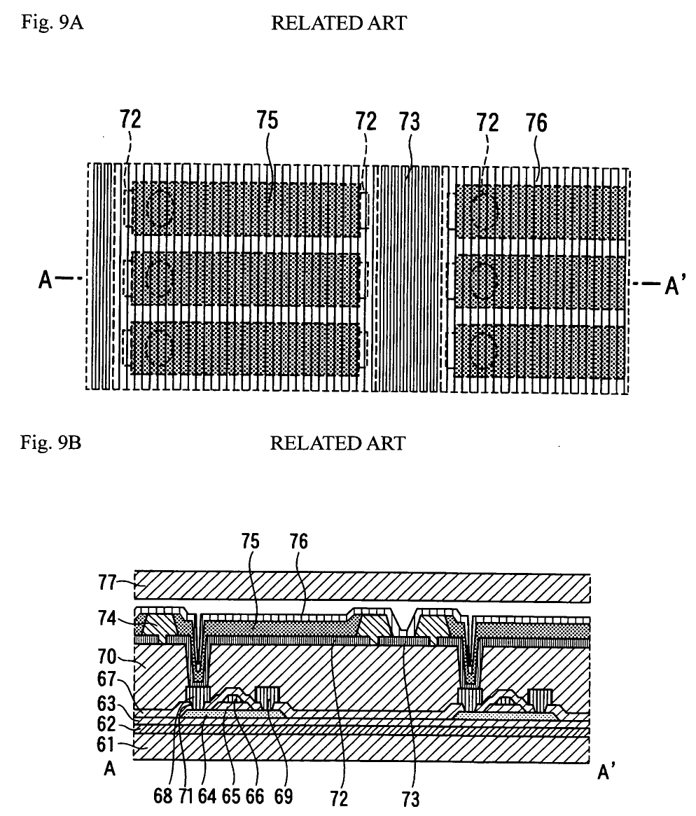

Next, with reference to FIGS. 7 and 8, a top emission type display apparatus of active matrix type using an organic EL device according to EXAMPLE 6 of the present invention will be described.

First, polycrystal silicon island-like regions 44 are formed on a first glass base substrate 41 with an SiN film 42 and an SiO₂ film 43 therebetween, and a gate electrode 46 made of Al is provided on the polycrystal silicon island-like regions 44 with a gate insulating film 45 made of an SiO₂ film therebetween; next, an SiO₂ film 47 is provided so as to cover the entire surface; and then openings for source/drain regions are formed, and source electrodes 48 and drain electrodes 49 of a Ti/Al/Ti structure are formed, whereby a TFT as an active element is formed.

Next, after applying positive-type photosensitive polyimide by the spin coating method, only the regions corresponding to the source electrodes 48 are exposed and developed, which is followed by baking to form a flattened insulating film 50 having openings for the source electrodes 48.

Next, an Al film is deposited over the entire surface and is patterned into a predetermined geometry, so that anodes 51 which are electrically connected to the source electrodes 48 are formed. Thereafter, a photosensitive acrylic resin is coated on the entire surface, and then is exposed and developed such that a convex insulating film 52 is left only in the regions between adjacent anodes 51.

Next, using a vapor deposition mask having openings which mask covers the convex insulating films 52, a hole injection layer, a hole transport layer, a luminescent layer, and an electron transport layer are sequentially vapor-deposited under heat to form an organic EL layer 53. Thereafter, the vapor deposition mask is removed, and a cathode 54 made of ITO is deposited over the entire surface.

Finally, similarly to EXAMPLE 1, the second glass base substrate 21 on which auxiliary electrodes 22 are formed is brought into such a position that the auxiliary electrode 22 is electrically connected to the cathode 54 above the convex insulating film 52, and a UV adhesive is used for sealing in a dried nitrogen atmosphere, whereby a top emission type display apparatus of active matrix type using an organic EL device according to EXAMPLE 6 of the present invention is completed.

The auxiliary electrodes 22 in this case are mutually electrically connected at the outer edge part of the second glass base substrate.

In EXAMPLE 7 of the present invention, since light is taken out from the second glass base substrate 21 side even though an active element is provided between the first glass base substrate 41 and the organic EL layer 53 as described above, the light emission area is not restricted by the active element.

Also in this case, the auxiliary electrodes 22 are provided on the second glass base substrate 21 side, thus the auxiliary electrodes 22 do not restrict the dedicated area for the organic EL layer 53, thereby enabling a high aperture ratio.

In addition, because the auxiliary electrodes 22 are connected to the cathode 54 at regions above the convex insulating film 52 (i.e., outside the pixel regions), it is understood that the existence of the auxiliary electrode 22 has no effect on the aperture ratio also in this regard.

Hereinabove, the respective examples of the present invention have been described; however, the present invention is not limited to the conditions and configuration described in the respective examples, but may be subjected to various alterations. For example, the materials constituting the organic EL layer mentioned in the above-described examples are only exemplary, and the materials for the organic layer may be appropriately selected from well-known organic EL materials in accordance with the desired emission color.

In addition, in the above-mentioned respective examples, ITO is used as a light transmitting material constituting the cathode; however, the material is not limited to ITO, and may be an oxide conductive material other than ITO, such as IZO or ZnO. A metallic thin film of Al, Ag, or the like that is thinned to approximately 20 mn may be used.

In addition, in the above-mentioned respective examples, Al is used as the anode material. However, the material is not limited to Al, and may be another highly reflective material such as Ag or Mo, or may be a laminate composed of a highly reflective material (such as Al) and an oxide conductive material (such as ITO), which may enhance the light emission efficiency.

The present invention is not limited to a pure top emission type display apparatus, but is applicable to a double-face emission type, with which light is taken out also from the first glass base substrate side. In this application, the anode material has to be a light transmitting conductive material having a light transmittance of 50% or higher, such as ITO, IZO, ZnO, an Ag thin film, or an Al thin film, or the like.

Except EXAMPLE 5, the first substrate and the second substrate are adhered to each other with a UV adhesive. However, as in EXAMPLE 5, an adhesive applied to the outside of the auxiliary electrode may be used to conduct the adhesion under heat and pressure. Further, a UV adhesive may be used also in EXAMPLE 5.

Although the black matrix is made of a black resin in EXAMPLE 3, the material is not limited to the black resin, and may be a conductive material such as Cr.

In addition, although the concavo-convex structure is formed by patterning a photosensitive resin in EXAMPLE 4, the surface of the glass base substrate may be roughened by a sandblasting treatment.

Although the auxiliary electrodes are formed in the shape of stripes in EXAMPLE 6, the auxiliary electrodes may be formed in the shape of a mesh (a matrix) since the cathode is a common electrode in the active matrix type. Also in this case, it is preferable that the auxiliary electrodes in the shape of a mesh be connected at the outer edge part of the second base substrate.

In addition, although EXAMPLE 6 has been described as an active matrix type variant of EXAMPLE 1, the configuration of the second base substrate side in an active matrix type display apparatus may be selected from the configurations described in EXAMPLE 2 to EXAMPLE 5. Further, a passive matrix type display apparatus or an active matrix type display apparatus may have a combination of the features or structures described in EXAMPLE 2 to EXAMPLE 5.

A glass base substrate is used as the first base substrate in the respective examples described above. However, in a top emission type display apparatus, the first base substrate need not be transparent, and may comprise a conductive base substrate made of stainless steel or the like, or an insulating opaque base substrate; therefore, the material for the base substrate is not restricted.

In the respective examples described above, light is taken out from the cathode side. However, such a structure may be inverted. For example, a cathode, an electron transport layer, a luminescent layer, a hole transport layer, a hole injection layer, and an anode may be deposited in this order from the first base substrate side such that light can be taken out from the anode side through the second base substrate.

In the respective examples described above, a TFT is used as an active element. However, the active element is not limited to a TFT, and, for example, a switching element having an MIM (metal-insulating film-metal)structure utilizing a diode—a two-terminal device—may be used.

In the respective examples described above, the cathode is provided directly on the electron transport layer. However, between the electron transport layer and the cathode, an electron injection layer made of an alkaline metal halide, i.e., CsF, LiF, NaF, KF, RbF, LiCl, LiBr, LiI, NaCl, NaBr, NaI, KCl, KBr, KI, RbCl, RbBr, RbI, CsCl, CsBr, or Csl, or the like, may be interposed.

The respective examples described above have been described as monochromatic display apparatuses. However, plural light emitting devices of different colors may be appropriately combined to provide a color display apparatus, and particularly, RGB light emitting devices may be combined to constitute a full-color display apparatus.

In the following, with reference back to FIG. 1, the detailed features of the present invention will be described again.

<1> An organic electroluminescence display apparatus comprising a first substrate 101 and a second substrate 102 adhered to the first substrate, wherein the first substrate 101 comprises a first base substrate 1 having an organic electroluminescence device 2; the organic electroluminescence device 2 comprises a first electrode 3, an organic electroluminescence layer 4, and a second electrode 5 provided in this order from the first base substrate side; the second substrate 102 comprises a second base substrate 6 and a patterned conductive film 7 that opposes the first substrate 101, and has a lower specific resistance than the second electrode 5; and the conductive film 7 is electrically connected to the second electrode 5.

<2> The organic electroluminescence display apparatus of <1>, wherein the second electrode 5 comprises a material having optical transparency.

<3> The organic electroluminescence display apparatus of <2>, wherein the second electrode 5 comprises at least one of a translucent metallic thin film or an oxide transparent conductive film.

<4> The organic electroluminescence display apparatus of any one of <1> to <3>, wherein the surface of the conductive film 7 that contacts the second base substrate 6 has a structure that prevents reflection of outside light.

<5> The organic electroluminescence display apparatus of <4>, wherein the structure that prevents reflection of outside light is either a concavo-convex structure or a black matrix.

<6> The organic electroluminescence display apparatus of any one of <1> to <5>, wherein the first substrate 101 is adhered to the second substrate 102 with a hot melt adhesive.

<7> The organic electroluminescence display apparatus of any one of <1> to <6>, further comprising a switching element provided on the first base substrate 1, wherein the switching element drives the organic electroluminescence device 2.

<8> The organic electroluminescence display apparatus of <7>, wherein the conductive film 7 is formed in the shape of stripes or in the shape of a matrix, and is connected to the second base substrate 6 at regions outside pixel regions.

<9> The organic electroluminescence display apparatus of any one of <1> to <8>, wherein the first electrode 3 comprises an opaque metallic film, and the second base substrate 6 side is the display surface.

<10> The organic electroluminescence display apparatus of any one of <1> to <8>, wherein the first electrode 3 comprises a material having optical transparency, and the first base substrate 1 side and the second base substrate 6 side are both the display surfaces.

As a typical application for the present invention, a display apparatus in the shape of a 2D matrix can be mentioned. However, the applications are not limited to display apparatuses, and also include large-sized single light sources, such as mood illumination light sources.

Therefore, according to embodiments of the present invention, improvement in aperture ratio and in manufacturing yield can be achieved when a transparent or translucent electrode is provided on the cathode side. In other words, in the present invention, an auxiliary electrode having a low specific resistance is provided on the second base substrate side opposite to the first base substrate, whereby the aperture ratio can be increased, and the manufacturing yield can be improved.

All publications, patent applications, and technical standards mentioned in this specification are herein incorporated by reference to the same extent as if each individual publication, patent application, or technical standard was specifically and individually indicated to be incorporated by reference.

What is claimed is:

1. An organic electroluminescence display apparatus comprising a first substrate and a second substrate adhered to the first substrate, wherein the first substrate comprises a first base substrate and an organic electroluminescence device; the organic electroluminescence device comprises a first electrode, an organic electroluminescence layer, and a second electrode provided in this order from the first base substrate side; the second substrate comprises a second base substrate and a patterned conductive film that opposes the first substrate, and has a lower specific resistance than the second electrode; and the conductive film is electrically connected to the second electrode.

2. The organic electroluminescence display apparatus according to claim 1, wherein a surface of the conductive film that contacts the second base substrate has a structure that prevents reflection of outside light.

3. The organic electroluminescence display apparatus according to claim 2, wherein the structure that prevents reflection of outside light is either a concavo-convex structure or a black matrix.

4. The organic electroluminescence display apparatus according to claim 1, wherein the first substrate and the second substrate are adhered to each other with a hot-melt adhesive.

5. The organic electroluminescence display apparatus according to claim 2, wherein the first substrate and the second substrate are adhered to each other with a hot-melt adhesive.

6. The organic electroluminescence display apparatus according to claim 1, further comprising a switching element provided on the first base substrate, wherein the switching element drives the organic electroluminescence device.

7. The organic electroluminescence display apparatus according to claim 6, wherein the conductive film is formed in the shape of stripes or in the shape of a matrix, and is connected to the second base substrate at regions outside pixel regions.

8. The organic electroluminescence display apparatus according to claim 2, further comprising a switching element provided on the first base substrate, wherein the switching element drives the organic electroluminescence device.

9. The organic electroluminescence display apparatus according to claim 8, wherein the conductive film is formed in the shape of stripes or in the shape of a matrix, and is connected to the second base substrate at regions outside pixel regions.

10. The organic electroluminescence display apparatus according to claim 1, wherein the second electrode comprises a material having optical transparency.

11. The organic electroluminescence display apparatus according to claim 10, wherein the second electrode comprises at least one of a translucent metallic thin film or an oxide transparent conductive film.

12. The organic electroluminescence display apparatus according to claim 1, wherein the first electrode comprises an opaque metallic film, and the second base substrate side is a display surface.

13. The organic electroluminescence display apparatus according to claim 2, wherein the first electrode comprises an opaque metallic film, and the second base substrate side is a display surface.

14. The organic electroluminescence display apparatus according to claim 1, wherein the first electrode comprises a material having optical transparency, and both of the first base substrate side and the second base substrate side are display surfaces.

15. The organic electroluminescence display apparatus according to claim 2, wherein the first electrode comprises a material having optical transparency, and both of the first base substrate side and the second base substrate side are display surfaces.
